(19) United States
(12) Patent Application Publication
(10) Pub. No.: US 2014/0154423 A1
(43) Pub. Date: Jun. 5, 2014

(54) APPARATUS AND METHOD FOR DEPOSITION

(71) Applicants: Yeong Deuk Jo, Seoul (KR); Seok Min Kang, Seoul (KR); Moo Seong Kim, Seoul (KR)

(72) Inventors: Yeong Deuk Jo, Seoul (KR); Seok Min Kang, Seoul (KR); Moo Seong Kim, Seoul (KR)

(73) Assignee: LG INNOTEK CO., LTD., Seoul (KR)

(21) Appl. No.: 14/128,902

(22) PCT Filed: Jun. 21, 2012
(86) PCT No.: PCT/KR2012/004918

§ 371 Date: Dec. 23, 2013

(30) Foreign Application Priority Data
Jun. 21, 2011 (KR) 10-2011-0060355

(51) Int. Cl. C23C 16/50

(52) U.S. Cl. CPC C23C 16/50
USPC 427/457; 118/723 R

(57) ABSTRACT

A deposition apparatus according to the embodiment includes a gas supply part for supplying a first gas; an ionization part connected to the gas supply part to supply a second gas, which is obtained by ionizing the first gas; and a reaction part into which the second gas is introduced to create a reaction. A deposition method according to the embodiment includes the steps of preparing a first gas; supplying a second gas, which is obtained by ionizing the first gas; and reacting the second gas with a substrate.

### TECHNICAL FIELD

The embodiment relates to an apparatus and a method for deposition.

### BACKGROUND ART

In general, among technologies to form various thin films on a substrate or a wafer, a CVD (Chemical Vapor Deposition) scheme has been extensively used. The CVD scheme results in a chemical reaction. According to the CVD scheme, a semiconductor thin film or an insulating layer is formed on a wafer surface by using the chemical reaction of a source material.

The CVD scheme and the CVD device have been spotlighted as an important thin film forming technology due to the fineness of the semiconductor device and the development of high-power and high-efficiency LED. Recently, the CVD scheme has been used to deposit various thin films, such as a silicon layer, an oxide layer, a silicon nitride layer, a silicon oxynitride layer, or a tungsten layer, on a wafer.

### DISCLOSURE OF INVENTION

### Technical Problem

The embodiment provides a deposition apparatus and a deposition method capable of improving the reliability of the deposition process and forming a thin film having a high quality.

### Solution to Problem

A deposition apparatus according to the embodiment includes a gas supply part for supplying a first gas; an ionization part connected to the gas supply part to supply a second gas, which is obtained by ionizing the first gas; and a reaction part into which the second gas is introduced to create a reaction.

A deposition method according to the embodiment includes the steps of preparing a first gas; supplying a second gas, which is obtained by ionizing the first gas; and reacting the second gas with a substrate.

### Advantageous Effects of Invention

The deposition apparatus according to the embodiment includes the ionization part. The ionization part incudes a polarity generation part and a charged particle generation part. Source gas introduced into the ionization part may be ionized, so that ionized gas can be supplied to the reaction part.

Since the ionized gas is supplied to the reaction part, the stable reaction may be carried out in the reaction part. In addition, ionized atoms are stably deposited on a substrate included in the reaction part, so that a thin film having the high quality can be formed. Further, the stable chemical reaction may be induced, so that the growth rate of the thin film can be improved and the thin film can be effectively controlled.

According to the related art, source gas is ionized in the reaction part, so the ion activation process is necessary to ionize the source gas. However, according to the embodiment, the source gas is ionized before the source gas is supplied to the reaction part, so the ion activation process can be omitted.

The charged particle generation part may generate charged particles. Thus, the ionization reaction of the source gas can be induced by the charged particles. In addition, the ionization reaction can be accelerated and controlled.

The deposition method according to the embodiment may perform the deposition process with the above-described effects.

### BRIEF DESCRIPTION OF DRAWINGS

FIG. 1 is a schematic view showing the structure of a deposition apparatus according to the embodiment.

FIG. 2 is an enlarged view of an ‘A’ portion shown in FIG. 1.

FIG. 3 is a flowchart showing a deposition process according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of a layer (or film), a region, a pattern, or a structure shown in the drawings may be modified for the purpose of convenience or clarity, the thickness and the size of elements may not utterly reflect an actual size.

Hereinafter, the embodiment will be described in detail with reference to accompanying drawings.

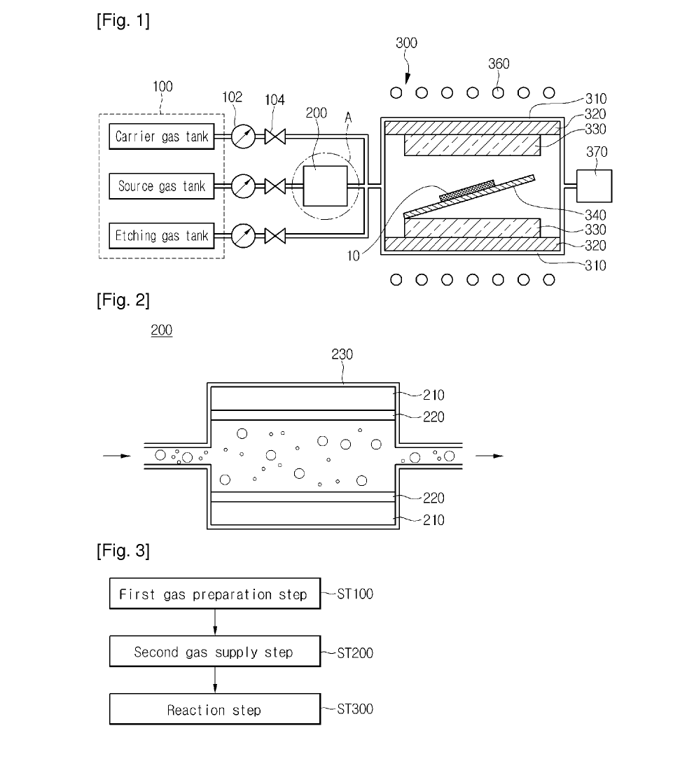

A deposition apparatus according to the embodiment will be described in detail with reference to FIGS. 1 and 2. FIG. 1 is a schematic view showing the structure of the deposition apparatus according to the embodiment. FIG. 2 is an enlarged view of an ‘A’ portion shown in FIG. 1.

Referring to FIGS. 1 and 2, the deposition apparatus according to the embodiment includes a gas supply part 100, an ionization part 200 and a reaction part 300.

The gas supply part 100 may include a plurality of gas tanks, a flow control valve 102 and a flow cut-off valve 106.

As shown in FIG. 1, the gas tank may include a carrier gas tank, a source gas tank and an etching gas tank.

The carrier gas stores carrier gas therein. The carrier gas tank may include inert gas, such as nitrogen (N₂) or hydrogen (H₂). The carrier gas may facilitate the transferring of the source gas. In addition, the carrier gas may facilitate the deposition process by forming the deposition atmosphere in the reaction part 300.

The source gas tank stores the source gas therein. The source gas tank may include various source gases including silicon (Si), such as silicon tetrachloride (SiCl₄), trichlorosilane (SiCl₃, TCS), methyltrichlorosilane (CH₃SiCl₃, MTS), dichlorosilane (SiH₂Cl₂), and silane (SiH₄). The source gas is used to deposit a thin film on a substrate included in the reaction part 300.

The etching gas tank stores etching gas therein. The etching gas is used to etch the substrate included in the reaction part 200.

The flow control valve 102 is provided in each of the carrier gas tank, the source gas tank and the etching gas tank. The flow control valve 102 can control the flow rate of gas contained in the gas tanks.

The flow cut-off valve 104 is provided in each of the carrier gas tank, the source gas tank and the etching gas tank. The flow cut-off valve 104 turned on/off to selectively supply gas contained in the gas tanks according to predetermined conditions.

The ionization part 200 may include a first chamber 230, a polarity generation part 210 and a charged particle generation part 220.

The first chamber 230 is connected to the source gas tank. The source gas stored in the source gas tank may be supplied to the first chamber 230.

The polarity generation part 210 is placed in the first chamber 230. The polarity generation part 210 may be connected to a power source. The polarity generation part 210 receives voltage from the power source to form an electric field in the first chamber 230. The polarity generation part 210 may generate positive polarity and negative polarity.

The polarity generation part 210 may ionize the source gas. That is, the polarity generation part 210 may ionic-dissociate the source gas. In detail, electrons that generate current in the first chamber 230 collide with the source gas to receive electros from the source gas. Thus, the source gas can be ionized.

The charged particle generation part 220 may generate charged particles. The charged particles are derivative particles to ionize the source gas. Therefore, the charged particle generation part 220 may induce the ionization reaction of the source gas. In addition, the charged particle generation part 220 may accelerate and control the ionization reaction.

As shown in FIG. 2, the source gas introduced into the ionization part 200 is ionized and the ionized source gas is supplied to the reaction part 300.

Since the ionized source gas is supplied to the reaction part 300, the stable reaction may be carried out in the reaction part 300. In addition, ionized atoms may be stably deposited onto the substrate included in the reaction 400, so that the thin film having the high quality can be formed. Further, the stable chemical reaction can be induced, so that the growth rate of the thin film can be improved and the thin film can be effectively controlled.

According to the related art, the source gas is ionized in the reaction part, so the ion activation process is necessary to ionize the source gas. However, according to the present embodiment, the source gas is ionized before the source gas is supplied to the reaction part, so the ion activation process can be omitted.

The reaction part 300 may include a second chamber 310, a heat generating element 360, a heat retaining unit 320, a susceptor 330, a substrate holder 340 and a vacuum pump 370.

The second chamber 310 has a cylindrical shape or a rectangular box shape and a predetermined cavity is formed in the second chamber 310 to proves the substrate 10. Although not shown in the drawings, a gas discharge port may be formed at one side of the second chamber 310 in order to discharge gas.

The second chamber 310 prevents the penetration of gas from the outside and maintains the vacuum degree. To this end, the second chamber 310 may include quartz having high mechanical strength and superior chemical durability.

The heat generating element 360 is provided outside the second chamber 310.

The heat generating element 360 may be a resistive heat generating element, which generates heat as electric power is applied thereto. A plurality of heat generating elements 360 may be aligned at a predetermined interval to uniformly heat the substrate 10. The heat generating element 360 may be prepared in the form of a wire. For instance, the heat generating element 360 may include a filament, a coil or a carbon wire.

The heat retaining unit 320 is provided in the second chamber 310. The heat retaining unit 320 may preserve the heat in the second chamber 310. In addition, the heat retaining unit 320 effectively transfers the heat generated from the heat generating element 360 to the susceptor 330.

The heat retaining unit 320 may be formed by using a chemically stable material, which is not deformed by the heat generated from the heat generating element 360. For instance, the heat retaining unit 320 may be formed by using nitride ceramic, carbide ceramic or graphite.

The susceptor 330 is positioned on the heat retaining unit 320.

In the deposition apparatus according to the embodiment, the substrate 10 on which deposits are formed or epitaxially grown may be placed on the susceptor 330.

Referring to FIG. 2, the susceptor 330 may include a susceptor upper plate, a susceptor lower plate, and susceptor side plates. In addition, the susceptor upper plate faces the susceptor lower plate.

The susceptor 330 can be manufactured by combining the susceptor upper plate, the susceptor lower plate and the susceptor side plates after placing the susceptor side plate at both lateral sides of the susceptor upper plate and the susceptor lower plate.

However, the embodiment is not limited to the above. For instance, the susceptor 330 can be manufactured by forming a cavity serving as a gas passage in the rectangular susceptor 330.

The substrate holder 340 may be located on the susceptor lower plate to fix the substrate 10 subject to the deposition process.

The deposition process may be performed while flowing air through a space between the susceptor upper plate and the susceptor lower plate. When the air flows in the susceptor 330, the susceptor side plates prevent the reaction gas from being discharged.

The susceptor 330 includes graphite representing a high heat resistance property and easily processed, so that the susceptor 30 can endure a high temperature condition. Since the graphite includes a porous material, the graphite may discharge absorption gas during the deposition process. In addition, the graphite reacts with the source gas, so that the surface of the susceptor may be changed into silicon carbide. Accordingly, silicon carbide may be added to the thin film of the susceptor.

The vacuum pump 370 can pump air contained in the second chamber 310. Thus, the interior of the second chamber 310 can be maintained in the vacuum state.

Hereinafter, the deposition method will be described with reference to FIG. 3. For the purpose of clear and simple explanation, the description about the parts equal to or substantially similar to the parts described above will be omitted and the following description will be focused on the different parts.

FIG. 3 is a flowchart showing the deposition method according to the embodiment.

Referring to FIG. 3, the deposition method according to the embodiment includes a first gas preparation step ST100, a second gas supply step ST200, and a reaction step ST300.

The source gas is prepared in first gas preparation step ST100.

Second gas supply step ST200 may include the step of ionizing the source gas. That is, the second gas can be supplied by ionizing the source gas.

Reaction step ST300 may include the step of forming the thin film on the substrate. The first gas may include silane, and the substrate may include silicon carbide. At this time, the thin film deposited on the substrate may include silicon carbide.

Second gas supply step ST200 and reaction step ST300 may be performed in different chambers. That is, the ionization of the first gas and the deposition of the second gas may be separately performed.

For instance, the source gas may include methyltrichlorosilane (MTS), and the MTS may be ionized. As the MTS is ionized, Si and Cl atoms contained in the MTS are supplied to the substrate. Thus, the thin film can be stably deposited on the substrate so that the thin film having the high quality can be formed.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A deposition apparatus comprising:
a gas supply part for supplying a first gas;
an ionization part connected to the gas supply part to supply a second gas, which is obtained by ionizing the first gas; and
a reaction part into which the second gas is introduced to create a reaction.

2. The deposition apparatus of claim 1, wherein the ionization part includes a polarity generation part connected to a power source to ionize the first gas by forming an electric field.

3. The deposition apparatus of claim 2, wherein the ionization part further includes a charged particle generation part for generating charged particles.

4. The deposition apparatus of claim 3, wherein the ionization part includes a chamber and the polarity generation part and the charged particle generation part are placed in the chamber.

5. The deposition apparatus of claim 4, wherein the polarity generation part generates an electric field in the chamber.

6. The deposition apparatus of claim 1, wherein the first gas include silane.

7. A deposition method comprising:
preparing a first gas;
supplying a second gas, which is obtained by ionizing the first gas; and
reacting the second gas with a substrate.

8. The deposition method of claim 7, wherein the supplying of the second gas comprises ionizing the first gas.

9. The deposition method of claim 7, wherein the supplying of the second gas and the reacting of the second gas with the substrate are performed in different chambers.

10. The deposition method of claim 7, wherein the reacting of the second gas with the substrate comprises forming a thin film on the substrate.

11. The deposition method of claim 7, wherein the first gas includes silane, and the substrate includes silicon carbide.

12. The deposition method of claim 10, wherein the thin film includes silicon carbide.
